(19) United States
(12) Patent Application Publication
(10) Pub. No.: US 2009/0194827 A1
(43) Pub. Date: Aug. 6, 2009

(54) Semiconductor Device Having Element Portion and Method of Producing the Same

(76) Inventors: Masahiro Ogino, Nukata-gun (JP); Minoru Murata, Obu-city (JP); Kazuhiko Sugiura, Nagoya-city (JP); Tetsuo Fujii, Toyohashi-city (JP)

Correspondence Address: POSZ LAW GROUP, PLC, 12040 SOUTH LAKES DRIVE, SUITE 101, RESTON, VA, 20191, US

(21) Appl. No.: 11/884,275

(22) PCT Filed: Apr. 25, 2006
(86) PCT No.: PCT/JP2006/308605

§ 371 Date: Aug. 14, 2007

(30) Foreign Application Priority Data
May 9, 2005 (JP) 2005-136094
Apr. 18, 2006 (JP) 2006-114641

(51) Int. Cl. H01L 29/84; H01R 43/02

(52) U.S. Cl. 257/415; 29/879; 257/E29.324

(57) ABSTRACT

A semiconductor device includes a semiconductor substrate, an element portion provided in the semiconductor substrate, and a connecting portion connected to the semiconductor substrate electrically, in which the connecting portion is formed of a conductive material in order to perform an electrical connection to an outside. The connecting portion is directly in contact with a surface of the semiconductor substrate such that the connecting portion and the semiconductor substrate are connected electrically.

### CROSS REFERENCE TO RELATED APPLICATIONS

This application is based on Japanese Patent Applications No. 2005-136094 filed on May 9, 2005 and No. 2006-114641 filed on Apr. 18, 2006, the disclosures of which are incorporated herein by reference.

### FIELD OF THE INVENTION

The present invention relates to a semiconductor device having an element portion and a method of producing the same.

### BACKGROUND ART

Conventionally, as a semiconductor device, a physical quantity sensor is proposed, in which a movable member as an element portion is formed on a semiconductor substrate. The movable member is displaceable in accordance with an applied physical quantity such as an acceleration and an angular speed. The sensor is disclosed in U.S. Pat. No. 6,792,805, for example.

In the semiconductor device, a bonding wire formed by a metallic wire bonding method or a bump formed by a ball bonding method is usually used as a connecting portion formed of a conductive material in order to perform an electrical connection to an outside.

In order to electrically connect the semiconductor substrate and the bonding wire or the bump as the connecting portion, conventionally, a patterning of a conductor film such as an electrode pad formed of a metallic film, e.g., aluminum, is formed on a surface of the semiconductor substrate by a photolithography method or the like.

Conventionally, after the element portion is formed in the semiconductor substrate by using the photolithography method and an etching technology, the electrode pad is formed. Then, after an appropriate time, the electrode pad on the semiconductor substrate and the connecting portion are connected electrically. The semiconductor device is produced in such a manner.

Thus, in the conventional semiconductor device, the electrode pad is additionally required in order to connect the connecting portion such as the bonding wire to the semiconductor substrate. Thereby, an increase in cost is caused.

Especially, in the physical quantity sensor, in which the movable member as the element portion such as an acceleration sensor and an angular speed sensor is formed in the semiconductor substrate, an electrical wiring by the conductor film is not required in the element portion. However, the patterning of the conductor film has to be formed for the electrode pad for the connecting portion. Thus, a problem of the increase in cost becomes more prominent.

### DISCLOSURE OF THE INVENTION

In view of the foregoing problems, it is an object of the present disclosure to provide a semiconductor device having an element portion. Further, it is another object to provide a method of producing a semiconductor device having an element portion.

According to a first aspect of the present disclosure, a semiconductor device includes a semiconductor substrate, an element portion provided in the semiconductor substrate, and a connecting portion connected to the semiconductor substrate electrically, in which the connecting portion is formed of a conductive material in order to perform an electrical connection to an outside. The connecting portion is directly in contact with a surface of the semiconductor substrate so that the connecting portion and the semiconductor substrate are connected electrically.

According to it, a conduction between the connecting portion and the semiconductor substrate can be appropriately secured without providing an electrode pad for the connecting portion on the semiconductor substrate in a conventional way. This is because the connecting portion and the semiconductor substrate are connected electrically by making the connecting portion to be directly in contact with the surface of the semiconductor substrate.

Therefore, according to the present disclosure, in the semiconductor device including the semiconductor substrate, the element portion provided in the semiconductor substrate and the connecting portion formed of the conductive material in order to perform the electrical connection to the outside, inexpensive construction can be realized, in which the electrode pad for the connecting portion is not required.

According to a second aspect of the present disclosure, a method of producing a semiconductor device includes a step of preparing a semiconductor substrate, a step of providing an element portion in the semiconductor substrate, and a step of connecting a connecting portion to the semiconductor substrate electrically, in which the connecting portion is formed of a conductive material in order to perform an electrical connection to an outside. The step of connecting includes a contacting step, in which the connecting portion is made to be directly in contact with a surface of the semiconductor substrate, and a forming step, in which a thermal treatment is performed at the contact portion. Thus, a reaction product portion is formed in the contact portion by reacting the conductive material constructing the connecting portion and a semiconductor constructing the semiconductor substrate.

According to it, the method of producing the semiconductor device can be provided, in which the semiconductor device having the reaction product portion can be appropriately produced.

### BRIEF DESCRIPTION OF THE DRAWINGS

The above and other objects, constructions and advantages of the present invention will become more apparent from the following detailed description made with reference to the accompanying drawings. In the drawings:

FIG. 1 is a plan view showing a schematic construction of a semiconductor device according to a first embodiment of the present invention;

FIG. 2A is a plan view of an acceleration sensor element in the semiconductor device shown in FIG. 1, and FIG. 2B is a schematic cross-sectional view of FIG. 2A;

FIG. 3 is a cross-sectional view of the acceleration sensor element taken along line III-III in FIG. 2A;

FIG. 4 is a cross-sectional view of the acceleration sensor element taken along line IV-IV in FIG. 2A;

FIG. 5 is a circuit diagram showing an example of a detection circuit in the semiconductor device shown in FIG. 1;

FIGS. 6A-6C are cross-sectional views showing a method of producing the semiconductor device shown in FIG. 1;

FIG. 7A is a plan view of an acceleration sensor element in a semiconductor device as a comparative example of the first embodiment, and FIG. 7B is a schematic cross-sectional view of FIG. 7A;

FIG. 8A is a plan view of an acceleration sensor element in a semiconductor device as a first modified example of the above-described embodiment, and FIG. 8B is a schematic cross-sectional view of FIG. 8A;

FIG. 9A is a plan view of an acceleration sensor element in a semiconductor device as a second modified example of the above-described embodiment, and FIG. 9B is a schematic cross-sectional view of FIG. 9A;

FIG. 10A is a plan view of an acceleration sensor element in a semiconductor device as a third modified example of the above-described embodiment, and FIG. 10B is a schematic cross-sectional view of FIG. 10A;

FIG. 11 is a plan view of an acceleration sensor element in a semiconductor device, in which a lead frame is used, according to a second embodiment of the present invention;

FIG. 12A is a plan view of a semiconductor device, in which a pressure sensor is used, according to a third embodiment of the present invention, and FIG. 12B is a schematic cross-sectional view of FIG. 12A;

FIG. 13A is a plan view of a semiconductor device as a first modified example of the above-described embodiment, and FIG. 13B is a schematic cross-sectional view of FIG. 13A; and

FIG. 14A is a plan view of a semiconductor device, in which a MOS is used, according to a fourth embodiment of the present invention, and FIG. 14B is a schematic cross-sectional view taken along line XIV-XIV in FIG. 14A.

### PREFERRED EMBODIMENTS OF THE INVENTION

### First Embodiment

The present disclosure relates to a semiconductor device, in which an element portion such as a movable member, a piezoresistance element, a hall element or a luminescence element is formed on a semiconductor substrate.

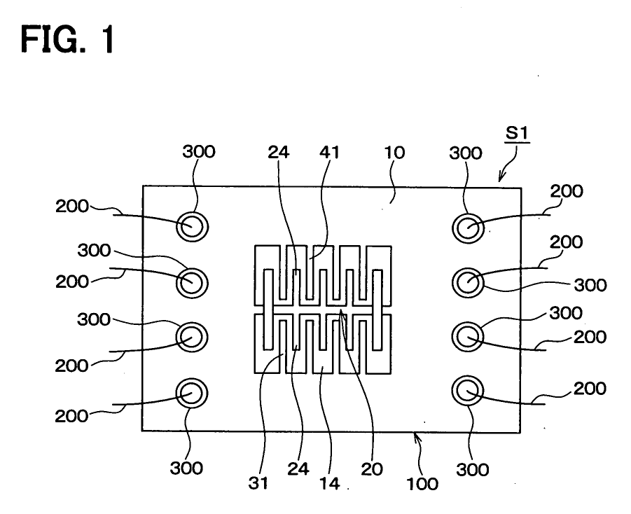

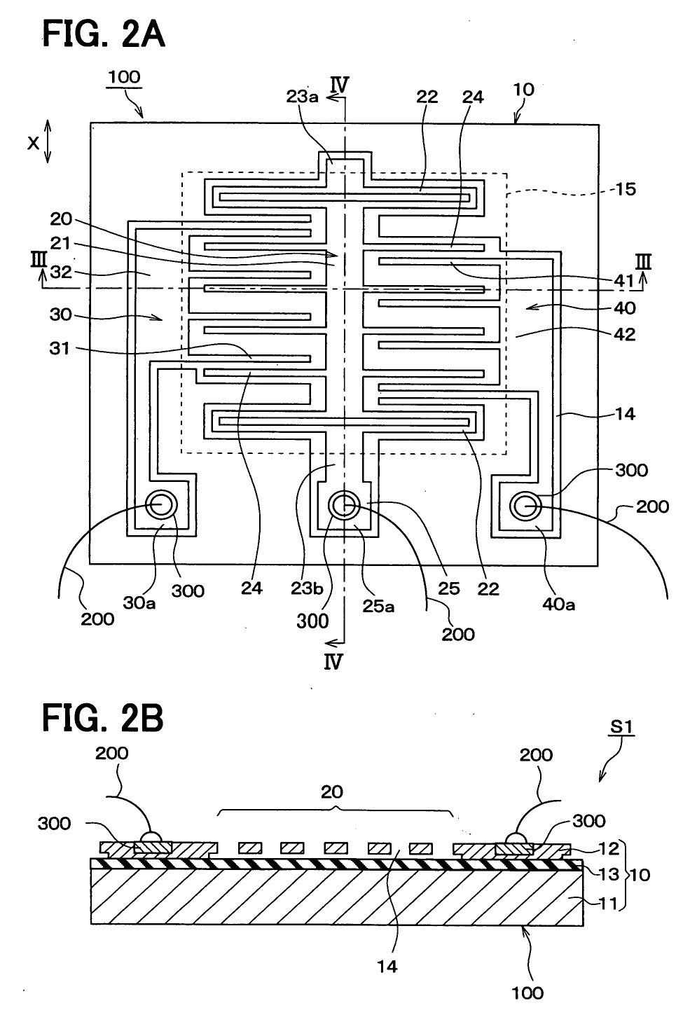

FIG. 1 is a view showing a schematic plan construction of an acceleration sensor S1 as a semiconductor device according to a first embodiment of the present invention. And, FIG. 2A is a plan view showing a detailed construction of an acceleration sensor element 100 in the acceleration sensor S1, and FIG. 2B is a schematic cross-sectional view of the acceleration sensor element 100 shown in FIG. 2A. In addition, a model cross-section is shown in FIG. 2B, in which a cross-section including a movable member 20 in the acceleration sensor element 100 in FIG. 2A and a cross-section adjacent to a connecting portion 200 are integrated.

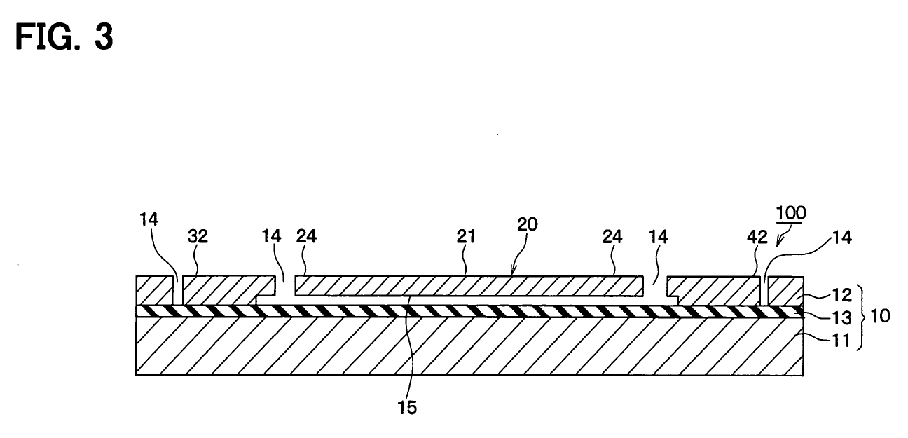

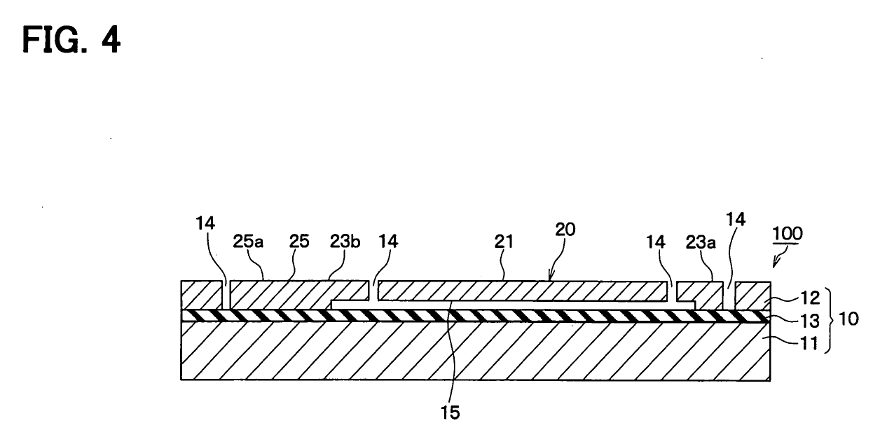

FIGS. 3 and 4 are schematic plan views showing a state, in which a bonding wire 200 is not connected to the acceleration sensor element 100, that is, a simple structure of the acceleration sensor element 100. FIG. 3 is a schematic cross-sectional view of the acceleration sensor element 100 taken along line III-III in FIG. 2A, and FIG. 4 is a schematic cross-sectional view of the acceleration sensor element 100 taken along line IV-IV in FIG. 2A.

For example, when the acceleration sensor S1 is mounted on an automobile, an acceleration of which is to be measured, the acceleration sensor S1 can be used for detecting the acceleration in accordance with an operation state of the automobile. However, this usage is not limited.

### [Construction]

As shown in FIG. 1, an acceleration sensor S1 in the first embodiment is constructed by electrically connecting a bonding wire 200 as a connecting portion to an acceleration sensor element 100. The acceleration sensor element 100 is formed by providing a movable member 20 as an element portion to a semiconductor substrate 10. The bonding wire 200 is formed of a conductive material in order to perform an electrical connection to an outside.

Here, in the acceleration sensor S1, the acceleration sensor element 100 may be directly mounted to an object to be measured. However, in the first embodiment, the acceleration sensor S1 is mounted to the object to be measured through a package (not shown). The mounting form of the acceleration sensor S1 to the object to be measured is not limited to this.

In the case in which the package is used, only the acceleration sensor element 100 is mounted to the package, or the acceleration sensor element 100 together with a circuit chip and the like is mounted to the package. And, through the package, the acceleration element 100 is mounted to an appropriate position of the object to be measured.

The mounting form of the acceleration sensor element 100 through this package has been conventionally performed. Here, the package can be formed of ceramic or resin, but the material of the package is not especially limited.

Specifically, the package is constructed as a multi-layered substrate, in which a plurality of ceramic layers, e.g., alumina layers, is stacked. A wiring can be formed on a surface of each ceramic layer or inside of a through hole formed in each ceramic layer.

The acceleration sensor element 100 and the package or a circuit chip are connected electrically by connecting the wiring of the package or the circuit chip in the package and the semiconductor substrate 10 constructing the acceleration sensor element 100 with the bonding wire 200.

Next, the acceleration sensor element 100 will be described with reference to FIGS. 2-4. The acceleration sensor element 100 is formed by performing a well-known micromachine process to the semiconductor substrate 10.

In the first embodiment, the semiconductor substrate 10 constructing the acceleration sensor element 100 is a rectangular SOI (silicon on insulator) substrate 10 having an oxide film 13 as an insulation layer. The oxide film 13 is sandwiched between a first silicon substrate 11 as a first semiconductor layer and a second silicon substrate 12 as a second semiconductor layer, as shown in FIGS. 3 and 4.

Here, in the first embodiment, the first silicon substrate 11 including the oxide film 13 is constructed as a supporting substrate. That is, a surface of the first silicon substrate 11 is constructed as the oxide layer 13, and the second silicon substrate 12 as the semiconductor layer is provided on the surface of the first substrate 11 to be the supporting substrate.

In the second silicon substrate 12, a groove 14 passing through in its thickness direction is formed, thereby a pattern is separated by the groove 14. That is, the movable member 20 as a movable portion and a beam structure having a comb teeth shape composed of fixed portions 30, 40 are formed.

Moreover, a corresponding area of the beam structures 20-40 in the second silicon substrate 12, i.e., a portion defined by a dashed rectangle 15 in FIG. 2A, is thin so as to be apart from the oxide film 13 (refer to FIGS. 3, 4).

The rectangle 15 is defined as a membrane portion 15 in the second silicon substrate 12. That is, the membrane portion 15 is positioned through a gap from the surface of the first silicon substrate 11 to be the supporting substrate, i.e., the oxide film 13.

In the acceleration sensor element 100, the movable member 20 as the membrane portion 15 is constructed such that both ends of an elongated quadrangle shaped weight portion 21 are integrally connected to anchor portions 23a, 23b through a spring portion 22.

As shown in FIG. 4, the anchor portions 23a, 23b are fixed to the oxide film 13, and supported on the first silicon substrate 11 as the supporting substrate through the oxide film 13. Thereby, the weight portion 21 and the spring portion 22, which are the membrane portion 15, are apart from the oxide film 13.

Here, as shown in FIG. 2A, the spring portion 22 is a rectangle frame shape, in which both ends of two parallel beams are connected to each other. The spring portion 22 has a spring function of being displaced in a direction perpendicular to the longitudinal direction of the two beams.

To be specific, when the spring portion 22 receives an acceleration including a component of an arrow X direction in FIG. 2A, the spring portion 22 displaces the weight portion 21 to the direction of the arrow X in a horizontal direction of the substrate. Then, the spring portion 22 restores the weight portion 21 to its initial state in accordance with a disappearance of the acceleration.

Therefore, the movable member 20 connected to the SOI substrate 10 through the spring portion 22 is displaceable in the direction of the arrow X in the horizontal direction of the substrate in accordance with the applied acceleration, the member 20 being disposed above the oxide film 13, i.e., the first silicon substrate 11 as the supporting substrate.

In addition, as shown in FIG. 2A, the movable member 20 includes a comb teeth shaped movable electrode 24 as the membrane portion 15. The movable electrode 24 is a plurality of beam shaped electrodes extending from the both sides of the weight portion 21 to the opposite directions in a direction perpendicular to the longitudinal direction (i.e., the arrow X direction) of the weight portion 21.

In other words, an array direction of the movable electrode 24 is the longitudinal direction of the weight portion 21 (i.e., displacing direction of the spring portion 22, and the arrow X direction). A plurality of the electrodes 24 is arrayed along the array direction and forms the comb teeth shape.

As shown in FIG. 2, the movable electrode 24 is formed on the left side and the right side of the weight portion 21. On each side, four of the electrodes 24 are projected. Each movable electrode 24 is formed in a beam shape having a rectangular cross-section, and in a state of being apart from the oxide film 13.

Each movable electrode 24 is displaceable in the direction of the arrow X in the horizontal direction of the substrate together with the spring portion 22 and the weight portion 21. This is because the electrode 24 is formed integrally with the spring portion 22 and the weight portion 21.

Moreover, as shown in FIGS. 2A-4, while the anchor portions 23a, 23b are supported on a facing edge of a periphery portion of the membrane portion 15, the fixed portions 30, 40 are supported on the other facing edge of the periphery portion so as to be fixed on the oxide film 13. And, the fixed portions 30, 40 are supported on the first silicon substrate 11 through the oxide film 13.

The fixed portion 30 positioned at the left side to the weight portion 21 in FIG. 2A is constructed by a left side fixed electrode 31 and a wiring portion 32 for the left side fixed electrode. In contrast, the fixed portion 40 positioned at the right side to the weight portion 21 in FIG. 2A is constructed by a right side fixed electrode 40 and a wiring portion 42 for the right side fixed electrode.

In the first embodiment, as shown in FIG. 2A, each of the fixed electrodes 31, 41 is included in a membrane portion 15. A plurality of the fixed electrodes 31, 41 is arrayed in a comb teeth shape so that the fixed electrodes 31, 41 can go into engagement with the clearance of the comb teeth in the movable electrodes 24.

Here, in FIG. 2A, in the left side to the weight portion 21, the left side fixed electrode 31 is provided in an upper side of each of the movable electrode 24 along the arrow X direction. In contrast, in the right side to the weight portion 21, the right side fixed electrode 41 is provided in a lower side of each of the movable electrode 24 along the arrow X direction.

Thus, each of the fixed electrodes 31, 41 is positioned so as to face each movable electrode 24 in the horizontal direction of the substrate. In each facing clearance, a detection clearance in order to detect a capacity is formed between the side face (i.e., detecting face) of the movable electrode 24 and the side face (i.e., detecting face) of the fixed electrodes 31, 41.

Further, the left side fixed electrode 31 and the right side fixed electrode 41 are electrically independent from each other. And, each of the fixed electrodes 31, 41 is formed in a beam shape having a rectangular cross-section and extending approximately parallel to the movable electrode 24.

Here, each of the left side fixed electrode 31 and the right side fixed electrode 41 is in a cantilever state supported by each of the wiring portions for the fixed electrodes 32, 42. The wiring portions 32, 42 are fixed on the first silicon substrate 11 through the oxide film 13. And, each of the fixed electrodes 31, 41 is apart from the oxide film 13.

In the first embodiment, as for the left side fixed electrode 31 and the right side fixed electrode 41, each of the plural electrodes is integrated to each wiring portion 32, 42, which is electrically common.

Moreover, predetermined positions of the wiring portion for the left side fixed electrode 32 and the wiring portion for the right side fixed electrode 42 are constructed as connecting portions 30a, 40a, to which the bonding wire 200 is connected.

Here, each of the wiring portions 32, 42 for the left side fixed electrode and the right side fixed electrode is extended to the periphery of the semiconductor substrate 10. Each of the connecting portions 30a, 40a for the left side fixed electrode and the right side fixed electrode is formed in the periphery.

Further, a wiring portion for the movable electrode 25 is formed such that the wiring portion 25 is integrally connected to the anchor portion 23b. A predetermined position in the wiring portion 25 is constructed as a connecting portion 25a, to which the bonding wire 200 is connected. That is, the predetermined position is constructed as the connecting portion 25a for the movable electrode.

Furthermore, in the semiconductor substrate 10 constructing the acceleration sensor element 100, a plurality of connecting portions practically exists, in addition to the connecting portions 25a, 30a, and 40a shown in FIG. 2A. The bonding wire 200 is connected to the connecting portions. And, the connecting form of the bonding wire 200 is shown in FIG. 1, for example.

In addition, as described above, the acceleration sensor element 100 is simply mounted to the package, or the acceleration sensor element 100 is mounted to the package together with the circuit chip and the like. The electrical connection between the acceleration sensor element 100 and the package is performed by connecting the wiring of the package and the semiconductor substrate 10 in the acceleration sensor element 100 with the bonding wire 200. The electrical connection between the acceleration sensor element 100 and the circuit chip is performed by connecting the circuit chip in the package and the semiconductor substrate 10 in the acceleration sensor element 100 with the bonding wire 200.

Here, as shown in FIG. 1, in the acceleration sensor element 100, the bonding wire 200 formed of a conductive metallic material is connected to a connecting portion such as the connecting portions 25a, 30a, and 40a (refer to FIG. 2A) in the semiconductor 10. In the first embodiment, the bonding wire 200 is made of aluminum (Al).

In the acceleration sensor S1 of the first embodiment, the bonding wire 200 as the connecting portion is directly in contact with the surface of the semiconductor substrate 10. In the contact portion, the bonding wire 200 and the semiconductor substrate 10 are connected electrically by forming a reaction product 300. The reaction product 300 is formed by reacting the conductive material constructing the bonding wire 200 and the semiconductor constructing the semiconductor substrate 10.

Here, in the first embodiment, the metal constructing the bonding wire 200 as the connecting portion is Al, the semiconductor constructing the semiconductor substrate 10 is silicon (Si), and the reaction product 300 is an Al—Si reacted layer 300 made of Al—Si.

Next, a detecting operation of the acceleration sensor S1 of the first embodiment will be described. In the first embodiment, an acceleration is detected based on a change of an electric capacitance between the movable electrode 24 and the fixed electrodes 31, 41 in accordance with the applied acceleration.

As described above, in the acceleration sensor element 100, the side faces (i.e., detecting faces) of the fixed electrodes 31, 41 are provided so as to face the side faces (i.e., detecting face) of the movable electrodes 24. The detection clearance in order to detect the capacitance is formed in each facing clearance of the side faces of the both electrodes.

Here, a first capacitance CS1 as a capacitance to be detected is formed in the clearance between the left side fixed electrode 31 and the movable electrode 24. In contract, a second capacitance CS2 as a capacitance to be detected is formed in the clearance between the right side fixed electrode 41 and the movable electrode 24.

In the acceleration sensor element 100, when an acceleration is applied in the arrow X direction in FIG. 2 in the horizontal direction of the substrate, the entire movable member 20 other than the anchor portions is integrally displaced in the arrow X direction by the spring function of the spring portion 22. Thus, the capacitances CS1, CS2 are changed in accordance with the displacement of the movable electrode 24 in the arrow X direction.

For example, in FIG. 2A, when the movable member 20 is displaced to a lower direction along the arrow X direction, the clearance between the left side fixed electrode 31 and the movable electrode 24 is widened, while the clearance between the right side fixed electrode 41 and the movable electrode 24 is narrowed.

Accordingly, the acceleration in the arrow X direction can be detected based on the change of a differential capacitance (CS1-CS2) by the movable electrode 24 and the fixed electrodes 31, 41. To be specific, a signal based on the capacitance difference (CS1-CS2) is output as an output signal from the acceleration sensor element 100. The signal is processed in the circuit chip provided in the package or in an external circuit and finally output.

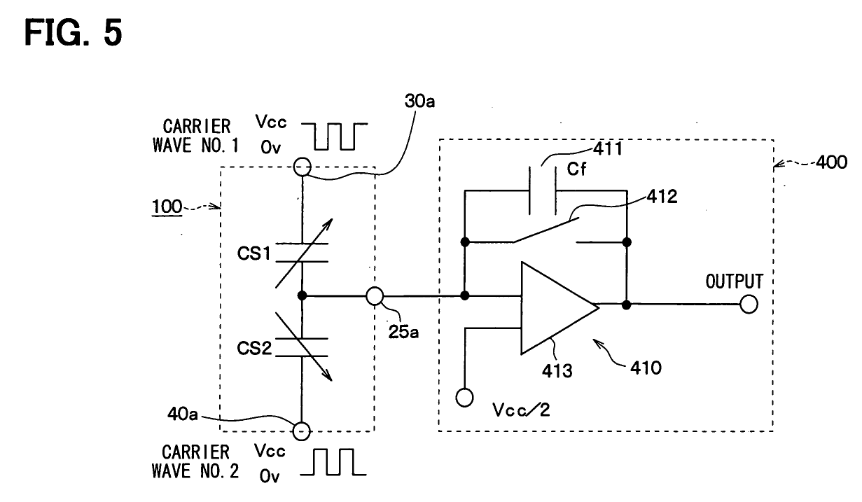

FIG. 5 is a circuit diagram showing an example of a detecting circuit 400 in order to detect an acceleration in the acceleration sensor S1 of the first embodiment.

In the detecting circuit 400, a switched capacitor circuit (SC circuit) 410 includes a capacitor 411, capacitance of which is Cf, a switch 412, and a differential amplification circuit 413. The circuit 410 transforms an input capacitance difference (CS1-CS2) to a voltage.

In the acceleration sensor S1, for example, a carrier wave No. 1, amplitude of which is Vcc, is input from the connecting portion 30a for the left side fixed electrode. A carrier wave No. 2, phase of which is lagged from the carrier wave No. 1 by 180°, is input from the connecting portion 40a for the right side fixed electrode. The switch 412 of the SC circuit 410 is opened and/or closed at a predetermined timing.

And, the applied acceleration in the arrow X direction is output as a voltage value V0 as shown in a following mathematical formula No. 1.

V0=(CS1−CS2)·Vcc/Cf (mathematical formula No. 1)

Thus, the detection of the acceleration can be performed.

### [Producing Method]

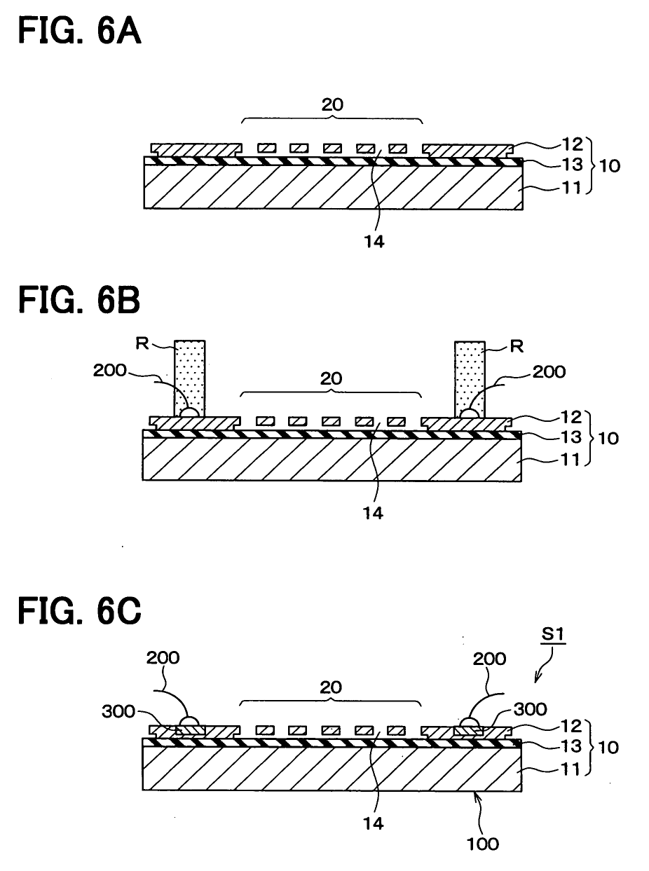

The acceleration sensor element 100 can be produced as described below, for example. FIGS. 6A-6C are process diagrams showing a method of producing the acceleration sensor S1 in the first embodiment shown in FIG. 1.

First, as shown in FIG. 6A, the SOI substrate 10 as the semiconductor substrate is prepared. In the surface of the SOI substrate 10, i.e., in the surface of the second silicon substrate 12, a high concentration impurity, e.g., P (phosphorus), B (boron) is injected, diffused, and doped. Thereby, in the surface of the second silicon substrate 12, a resistivity is lowered so that a conducting property is provided.

And, a mask is formed in the second silicon substrate (SOI layer) 12 of the SOI substrate 10 by using a photolithograph technology. The shape of the mask is corresponding to the beam structure. Then, a trench 14 is formed by a trench etching, e.g., dry etching by using a gas, e.g., CF₄ or SF₆, so that the pattern of the beam structures 20-40 can be formed at one time.

Subsequently, the etching continues. The lower part of the second silicon substrate 12 is removed by a side etching so that the membrane portion 15 is formed. The acceleration sensor element 100 can be produced, in which the movable member 20 released as the element portion is provided in the SOI substrate 10.

In addition, because the acceleration sensor element 100 is usually produced by using the SOI substrate 10 as a wafer, then, the acceleration sensor element 100 is divided into chips. The acceleration sensor element 100 is fixed to the package through an adhesive or the like, and a wire bonding is formed. Thus, the bonding wire 200 can be formed.

In the wire bonding process, as shown in FIG. 6B, the bonding wire 200 is directly in contact with the surface of the SOI substrate 10, i.e., surface of the second silicon substrate 12. In this state, a thermal process is performed on the contact portion of the bonding wire 200 and the SOI substrate 10.

Here, specifically, the bonding wire 200 is in contact with the contact portion, i.e., the connecting portions 25a, 30a, 40a, and the like, on the surface of the SOI substrate 10, by an ordinary wire bonding method. As shown in FIG. 6B, the thermal process is performed by irradiating a laser R locally to the contact portion.

Moreover, in the first embodiment, the connecting portion is the bonding wire 200. The thermal process may be performed at the same time as the wire bonding is performed on the surface of the SOI substrate 10, or after the wire bonding is performed.

That is, the laser R irradiation may be performed at the same time as the bonding wire 200 is in contact with the SOI substrate 10, or after the connecting between the SOI substrate 10 and the package or the circuit chip by the wire bonding is finished.

Thereby, as shown in FIG. 6C, in the contact portion of the bonding wire 200 and the SOI substrate 10, the reaction product 300 is formed by reacting the metal constructing the bonding wire 200 and the semiconductor constructing the SOI substrate 10.

Here, Al constructing the bonding wire 200 and Si constructing the SOI substrate 10 generate a solid-phase reaction by heating with the laser R irradiation. Therefore, the Al—Si reacted layer 300 made of Al—Si alloy is formed as the reaction product.

Accordingly, the forming of the element portion 20 in the SOI substrate 10 as the semiconductor substrate 10, and the connecting of the bonding wire 200 as the connecting portion are finished. Then, a sealing and the like is performed to the package. Accordingly, the acceleration sensor S1 in the first embodiment shown in FIG. 1 can be produced.

### [Effect]

Here, according to the first embodiment, in a semiconductor device S1 including a semiconductor substrate 10, an element portion 20 provided in the semiconductor substrate 10, and a connecting portion 200 formed of a conductive material, in which the connecting portion 200 is connected to the semiconductor substrate 10 electrically in order to perform an electrical connection to an outside, the connecting portion 200 is directly in contact with the surface of the semiconductor substrate 10. A reaction product 300 reacted from the conductive material constructing the connecting portion 200 and the semiconductor constructing the semiconductor substrate 10 is formed in the contact portion. Accordingly, the semiconductor device S1 characterized by the electrical connection between the connecting portion 200 and the semiconductor substrate 10 can be provided.

According to the semiconductor device in the first embodiment having this kind of characteristics, a conduction between the connecting portion 200 and the semiconductor substrate 10 can be appropriately secured even if an electrode pad for the connecting portion is not provided in the semiconductor substrate in a conventional way. This is because the connecting portion 200 and the semiconductor substrate 10 are electrically connected by forming the reaction product 300 reacted from the conductive material constructing the connecting portion 200 and the semiconductor constructing the semiconductor substrate 10 in the contact portion after the connecting portion 200 is directly in contact with the surface of the semiconductor substrate 10.

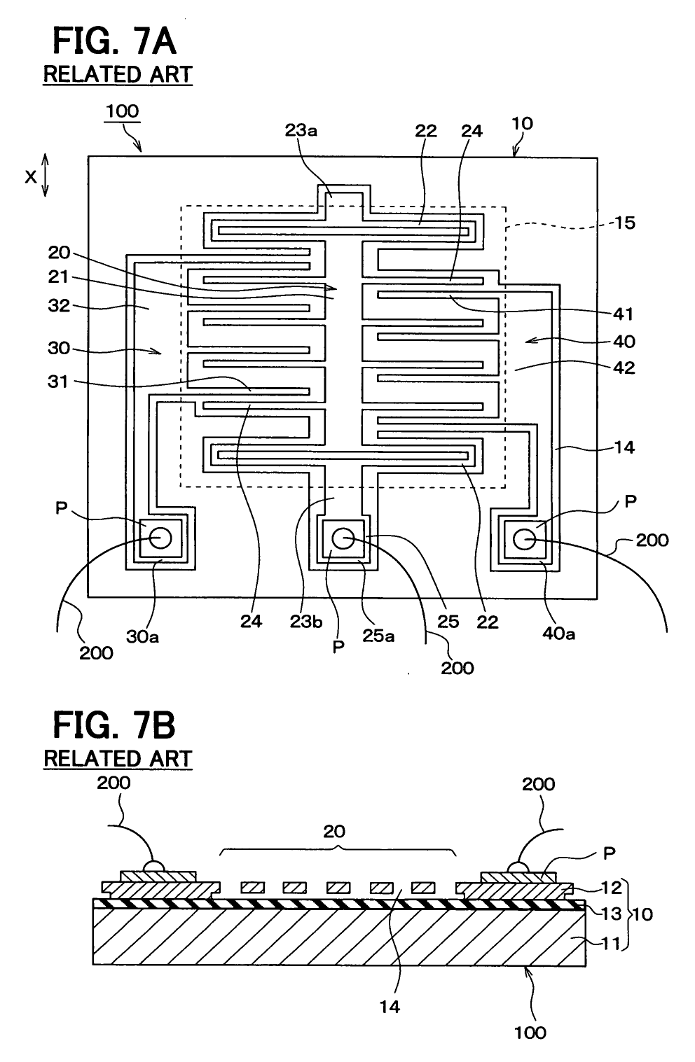

Here, FIG. 7A is a schematic plan view of an acceleration sensor element in an acceleration sensor as a comparative example, and FIG. 7B is a schematic cross-sectional view of FIG. 7A. Objects shown in FIGS. 7A, 7B are prototypes the present inventors made. In the prototypes, an electrode pad P made of Al and the like is formed at connecting portions 25a, 30a, and 40a of the connecting portion 200 in the semiconductor substrate 10. In contrast, in the first embodiment, the electrode pad P is unnecessary.

Therefore, according to the first embodiment, in the semiconductor device S1 including the semiconductor substrate 10, the element portion 20 provided in the semiconductor device 10, and the connecting portion 200 formed of the conductive material in order to perform the electrical connection to the outside, the electrode pad for the connecting portion is unnecessary. Accordingly, an inexpensive structure can be realized.

Further, in the first embodiment, the element portion 20 is a movable member 20 displaceable to the semiconductor substrate 10 in accordance with an applied acceleration, which is a physical quantity. Accordingly, the acceleration sensor S1 as the semiconductor device is provided.

In addition, in the acceleration sensor S1 according to the first embodiment, to adopt the bonding wire 200 as the connecting portion is one of the characteristics.

Moreover, in the acceleration sensor S1 according to the first embodiment, the conductive material constructing the bonding wire 200 as the connecting portion is Al, and the semiconductor constructing the semiconductor substrate 10 is Si. Thus, the Al—Si reacted layer 300 is made of Al—Si as the reaction product. That is also one of the characteristics.

That is, by bonding the bonding wire 200 made of Al directly on the surface of the semiconductor substrate 10, the alloy (aluminum alloy) of the Al constructing the wire 200 and the Si constructing the substrate 10 is formed in the interface of the wire 200 and the substrate 10. Therefore, the electrical connection is performed by an ohmic contact between the wire 200 and the substrate 10.

Further, according to the first embodiment, as shown in FIGS. 6A-6C, in the producing method of the semiconductor device, the semiconductor substrate 10 is prepared, the element portion 20 is provided in the semiconductor substrate 10, and the connecting portion 200 formed of the conductive material in order to perform the electrical connection to the outside is electrically connected to the semiconductor substrate 10. The connecting portion 200 is directly in contact with the surface of the semiconductor substrate 10, and the thermal treatment is performed to the contact portion in this state. Thus, the producing method of the semiconductor device S1 can be suggested, in which the device S1 is characterized by forming the reaction product 300. The product 300 is formed by reacting the conductive material constructing the connecting portion 200 and the semiconductor constructing the semiconductor substrate 10 in the contact portion.

According to it, the method of producing the semiconductor device can be provided, in which the acceleration sensor S1 as the semiconductor device according to the first embodiment shown in each of the figures can be appropriately produced.

Here, as shown in FIGS. 6A-6C, in the method of producing the semiconductor device according to the first embodiment, to perform the thermal treatment by irradiating the laser R locally to the contact portion between the connecting portion 200 and the semiconductor substrate 10 is one of the characteristics.

Moreover, as described above, in the method of producing the semiconductor device according to the first embodiment, in a case in which the connecting portion is the bonding wire 200, to perform the thermal treatment at the same time as the wire bonding is performed on the surface of the semiconductor substrate 10 is one of the characteristics.

In contrast, as described above, in the method of producing the semiconductor device according to the first embodiment, in the case in which the connecting portion is the bonding wire 200, to perform the thermal treatment after the wire bonding is performed on the surface of the semiconductor substrate 10 is also one of the characteristics.

### Modified Examples

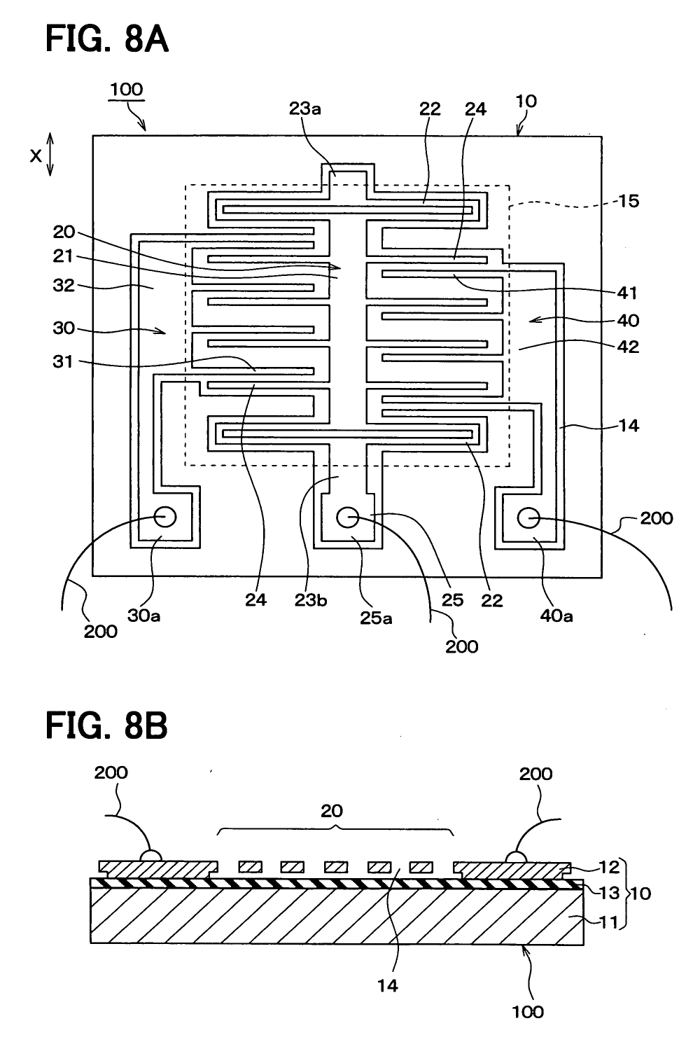

Here, a variety of modified examples of the first embodiment will be described. FIG. 8A is a schematic plan view of the acceleration sensor element 100 in the acceleration sensor as a first modified example, and FIG. 8B is a schematic cross-sectional view of FIG. 8A. In addition, a cross-sectional view of following figures showing each modified example shows a model cross-sectional view similar to FIG. 2B, in which a cross-sectional view including a movable member 20 in the acceleration sensor element 100 and a cross-sectional view adjacent to a connecting portion 200 are integrated.

In an example shown in FIG. 2B, the connecting portion 200 is directly in contact with the surface of the semiconductor substrate 10. The connecting portion 200 and the semiconductor substrate 10 are electrically connected by forming the reaction product 300 in the contact portion. Alternatively, the reaction product may not exist like the present first modified example.

In the case in which the reaction product does not exist, as long as the electrical connection between the semiconductor substrate 10 and the connecting portion 200 is secured, the substrate 10 and the connecting portion 200 have only to be in contact with each other by a pressure bonding and the like without the reaction product.

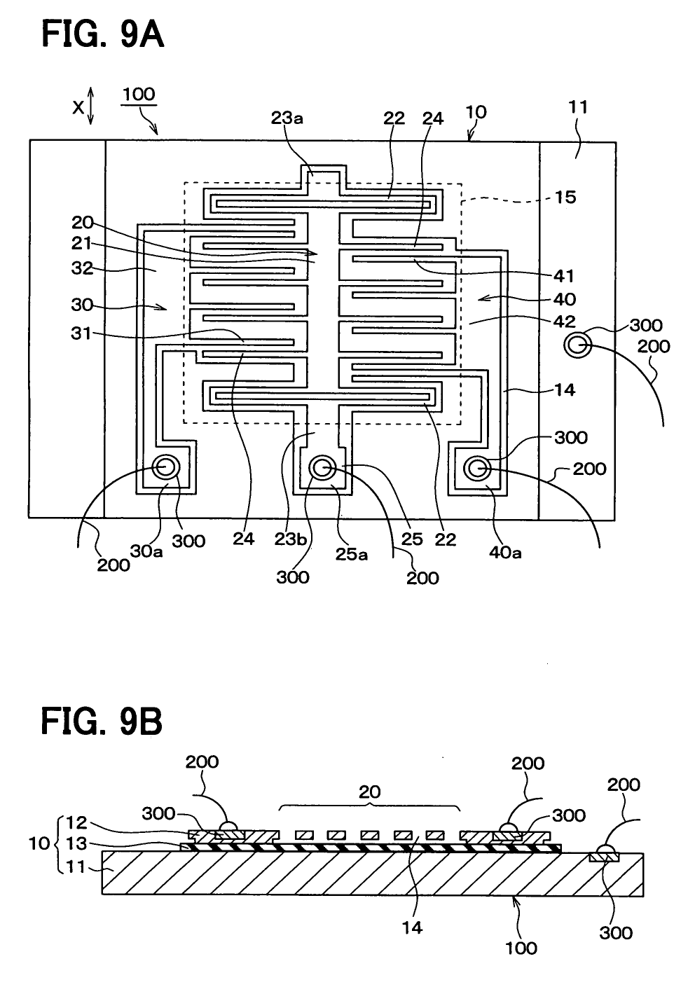

Further, FIG. 9A is a schematic plan view of an acceleration sensor element 100 in an acceleration sensor, which is a semiconductor device as a second modified example of the first embodiment, and FIG. 9B is a schematic cross-sectional view of FIG. 9A.

As shown in FIGS. 9A, 9B, in the present example, the bonding wire 200 is directly in contact with the surface of the semiconductor substrate 10. In the contact portion, the bonding wire 200 and the semiconductor substrate 10 are electrically connected by forming the reaction product 300 made of the Al—Si reacted layer and the like. The reaction product 300 is formed by the conductive material such as Al constructing the bonding wire 200 and the semiconductor such as Si constructing the semiconductor substrate 10.

And, in the acceleration sensor of the present example, the same effect as that of the acceleration sensor S1 shown in FIGS. 1, 2A and 2B can be obtained sufficiently.

Here, as shown in FIGS. 9A, 9B, in the semiconductor substrate 10, the oxide film 13 and the second silicon substrate 12 are removed in the periphery of the first silicon substrate 11 by an etching. Therefore, the periphery of the first silicon substrate 11 is exposed. This is an original structure peculiar to the present example. And, the exposed portion of the first silicon substrate 11 is constructed as the connecting portion capable of connecting to the bonding wire 200.

In this case, in the semiconductor substrate 10, the surfaces for connecting the bonding wires 200 are not on the same flat, thereby a bump is generated between the surfaces.

In contrast, in a conventional art, before forming the element portion in the semiconductor substrate by the etching, an electrode pad made of the conductive film such as Al has to be formed in the connecting portion in the semiconductor substrate, to which the bonding wire is connected. Therefore, in the conventional art, to form the electrode pad in the first silicon substrate 11 is difficult so that the wire bonding is difficult in the bump structure.

In the point, according to the second modified example shown in FIGS. 9A, 9B, the electrical connection of the bonding wire 200 to the first silicon substrate 11 can be easily performed. The bonding wire 200 is directly in contact with the surface of the first silicon substrate 11, and the reaction product 300 between the metal constructing the bonding wire 200 and the Si constructing the first silicon substrate 11 is formed in the contact portion. Thus, an electrical potential of the substrate can be formed.

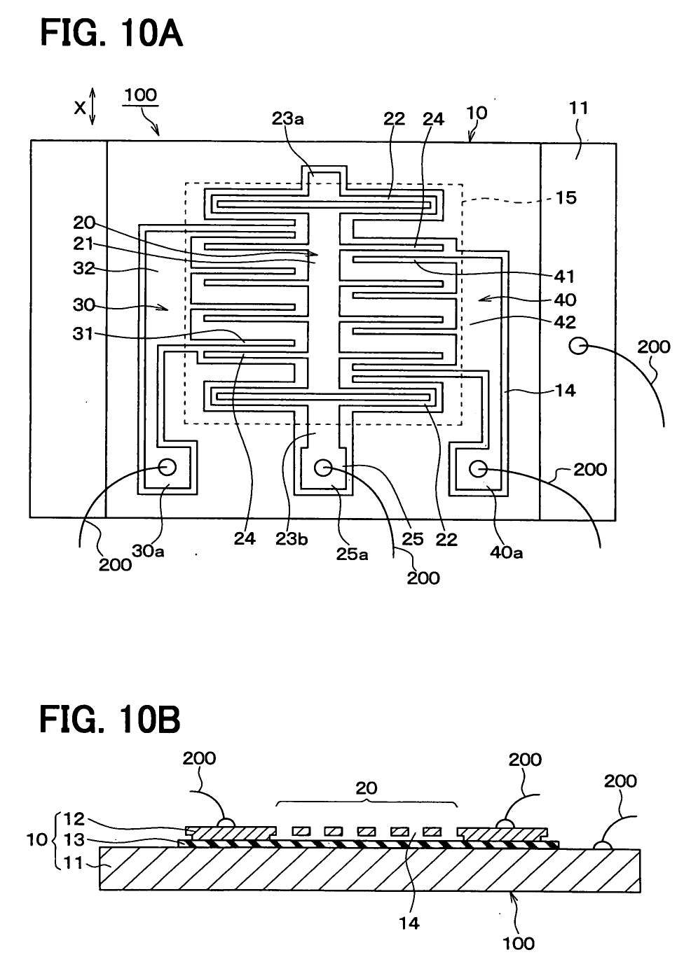

Moreover, FIG. 10A is a schematic plan view of an acceleration sensor element 100 in an acceleration sensor as a third modified example, and FIG. 10B is a schematic cross-sectional view of FIG. 10A. The reaction product in the acceleration sensor element 100 shown in FIG. 9 is removed in the acceleration sensor element 100 shown in FIG. 10. And, in each of the modified examples, the effect of the first embodiment described above can be achieved sufficiently.

### Second Embodiment

In the contact portion between the bonding wire 200 and the semiconductor substrate 200, the conductive material constructing the bonding wire 200 may cut into the semiconductor substrate 10 in a wedge shape. That is, an alloy spike may be generated.

In this case, in the interface between the bonding wire 200 and the semiconductor substrate 10, the conductive material constructing the bonding wire 200 and the semiconductor constructing the semiconductor substrate 10 generate a solid-phase reaction. Thus, a reaction product made of Al—Si alloy and the like is formed. Therefore, the bonding wire 200 and the semiconductor substrate 10 are electrically connected.

Further, in the above-described embodiment, the examples are shown, in which the SOI substrate 10 is used as the semiconductor substrate 10, and the bonding wire 200 mainly made of Al is used as the connecting portion 200. However, the combination of the semiconductor constructing the semiconductor substrate 10 and the conductive material constructing the bonding wire 200 is not limited to the above examples.

That is, the electrical connection has only to be secured by the combination of the semiconductor and the conductive material, and favorably the solid-phase reaction may be generated so that the reaction product is formed. For example, the semiconductor constructing the semiconductor substrate 10 may be a single crystal Si, a poly crystal Si or an amorphous Si, which are bulk solids, or a compound semiconductor such as GaAs or GaN.

Moreover, the doping of the impurity to the semiconductor substrate 10 is required only for the electrical connection to the conductive material constructing the connecting portion 200, and any conductive type will be accepted.

Further, in the above-described embodiment, Al is described as the example of the connecting portion. Alternatively, for example, metal, e.g., gold or copper, its alloy, organic conductor or semiconductor other than the Al may be used for the conductive material constructing the connecting portion. However, the thermal treatment is preferably performed in a condition, in which the solid-phase reaction can be generated in the interface of the semiconductor substrate 10 and the connecting portion.

Furthermore, in the above-described embodiment, the contact portion of the semiconductor substrate 10 and the bonding wire 200 is locally heated, as an example. Alternatively, for example, a heater is provided in the semiconductor substrate 10 side, and the semiconductor substrate 10 may be heated in total. In this case, the thermal treatment can also be performed at the same time as the wire bonding is performed on the surface of the semiconductor substrate 10 or after the wire bonding is performed.

In addition, the connecting portion 200 is not limited to the bonding wire 200. For example, a bump formed on the surface of the semiconductor substrate 10 by a ball bonding and the like may be used as the connecting portion. Moreover, not through the bonding wire, a lead frame may be directly in contact with the semiconductor substrate 10 so that the electrical connection is performed.

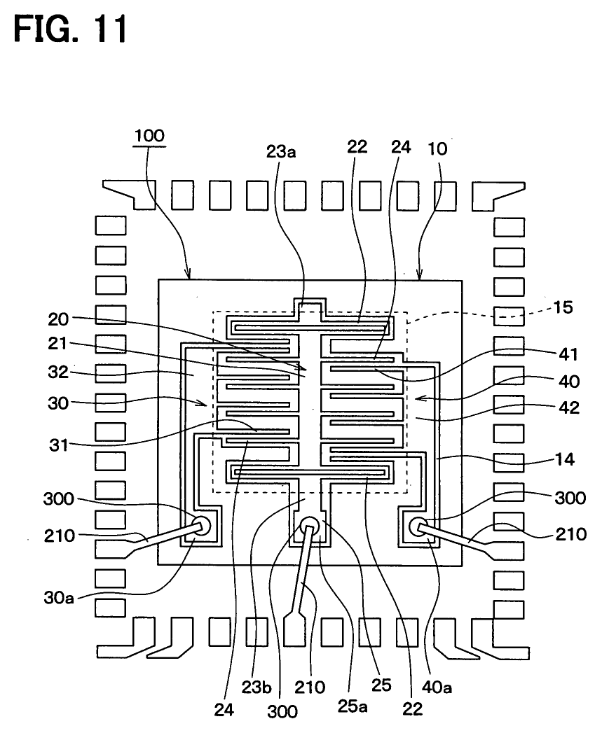

FIG. 11 is a schematic plan view of an acceleration sensor element in an acceleration sensor, in which a lead frame 210 is used for the connecting portion, as a second embodiment.

In the acceleration sensor shown in FIG. 11, the lead frame 210 is disposed around the acceleration sensor element 100, and the lead frame 210 and the semiconductor substrate 10 constructing the acceleration sensor element 100 are connected electrically.

Here, the lead frame 210 is constructed with a common lead frame material having a conductive property, for example, with copper, 42-alloy or the like. And, in the example shown in FIG. 11, a reaction product 300 reacted between the conductive material constructing the lead frame 210 and the semiconductor constructing the semiconductor substrate 10 is formed.

To be specific, the connection of the lead frame 210 in the present example can be performed by the laser irradiation based on the producing method shown in the above-described embodiment. The reaction product 300 in the present example may be made of Cu—Si or Fe—Si, for example. In addition, in the acceleration sensor element shown in FIG. 11, the reaction product may not exist.

Further, in the above-described embodiment, the bonding of the connecting portion 200 is performed in a state in which the semiconductor substrate 10 is divided into the chips, as an example. However, this invention can be applied to a bonding in a substrate condition, i.e., wafer condition.

Furthermore, in the all cases of the above-described embodiment, the laser is irradiated to the surface of the semiconductor substrate including the connecting portion, before the bonding of the connecting portion, so that an asperity is formed on the surface of the substrate. Thus, the contact area of the semiconductor substrate and the connecting portion is increased and this increase is effective.

In addition, in the acceleration sensor of the above-described embodiment, the release of the movable member 20 is performed by forming the membrane portion 15 on the second silicon substrate 12 such that the oxide film 13 is left in the all area of the SOI substrate 10. Alternatively, as well-known, the release of the movable member 20 may be performed by etching at the cost of the oxide film 13 in the SOI substrate 10.

In the case in which the sacrifice-layer etching method is performed, the thickness of the second silicon substrate 12 is almost homogeneous in the all area. The release of the movable member 20 from the supporting substrate is performed by removing the oxide film 13 in the rectangle part 15 shown in FIG. 2.

Moreover, in the above-described embodiment, a topside processing type acceleration sensor is described, in which the etching process is performed from the topside of the semiconductor substrate 10 so that the movable member 20 as the element portion is released. Alternatively, the release of the movable member may be performed by the etching from the backside of the semiconductor substrate 10, i.e., the first silicon substrate 11 in the above examples, that is a backside processing type acceleration sensor.

Further, in the above-described embodiment, the example of the acceleration sensor is described, in which the element portion is the movable member displaceable to the semiconductor substrate in accordance with the applied physical quantity. Alternatively, the acceleration sensor having the movable member as the element portion may be an angular speed sensor (gyro sensor), for example. The movable member performs a detection by Coriolis force when an angular speed as the physical quantity is applied by driving the movable member.

Furthermore, in the semiconductor device capable of being applied in the present invention, the element portion is provided in the semiconductor substrate. The element portion may be formed not only by processing the semiconductor substrate in the semiconductor process. For example, a part as the element portion may be fixed to the semiconductor substrate by adhesive and the like.

That is, the present invention is effective in the structure, in which the wiring by the metallic film is not required in the semiconductor substrate. The present invention can be applied not only to the movable sensors, i.e., the acceleration sensor and the gyro sensor, but also to the other semiconductor devices, for example, devices having a piezoresistance element made of a diffusion layer, a hall element, a luminescence element such as a luminescence diode, laser or the like, or a solar battery.

Moreover, in the above-described embodiment of the acceleration sensor, the element portions 20 are separated from each other by the groove 14. However, the separation of the element portions is not limited to the groove separation. Alternatively, an electrical separation method, e.g., a PN-junction, or a separation method using an insulating film can be applied, for example.

### Third Embodiment

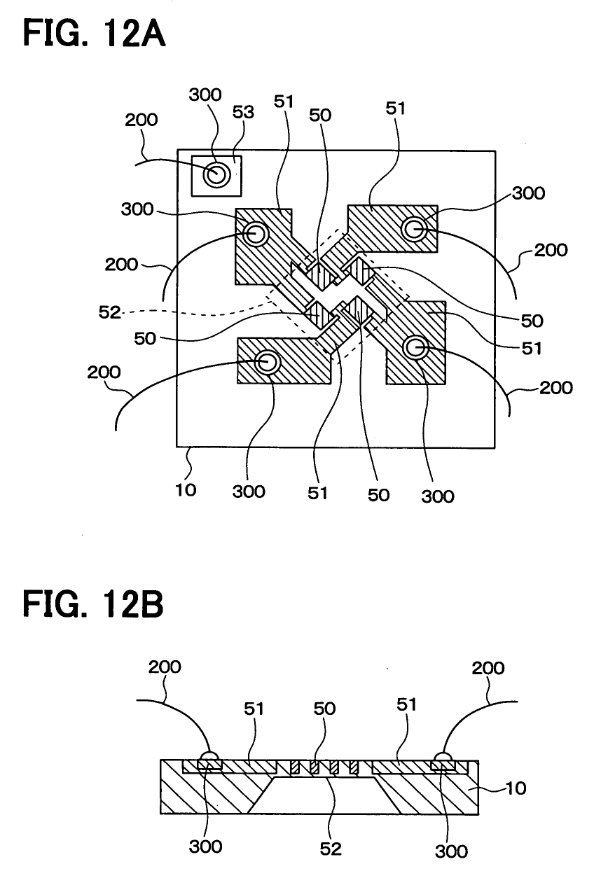

Here, as a semiconductor device of the present invention, an example of a pressure sensor is shown in FIGS. 12A, 12B, in which a separation of an element portion is performed by a PN-junction. FIG. 12A is a schematic plan view of the pressure sensor, and FIG. 12B is a schematic cross-sectional view of FIG. 12A. In addition, in FIG. 12A, a gauge 50 and a wiring 51 construct the element portion, and hatching is performed on the gauge 50 and the wiring 51 for identification.

The pressure sensor is formed by arranging the gauge 50 and the wiring 51 as the element portion in a semiconductor substrate 10 made of Si and the like. The pressure sensor is constructed by electrically connecting a bonding wire 200 as a connecting portion to the wiring 51. The bonding wire 200 enables the pressure sensor to electrically operate to and from an outside circuit.

Here, in the pressure sensor, a diaphragm 52 is formed by etching. The gauge 50 and the wiring 51 are formed in the diaphragm 52, and a bridge circuit is constructed by the gauge 50 and the wiring 51. Then, when a pressure is applied, the diaphragm 52 is distorted. The applied pressure is detected based on an output change of the bridge circuit by the distortion.

The pressure sensor like this is a general semiconductor diaphragm type pressure sensor. For example, the semiconductor substrate 10 is N-type silicon, and the gauge 50 and the wiring 51 are P-type diffusion layers formed by an injection and diffusion of B (boron) and the like.

Then, the bonding wire 200 is electrically connected to the wiring 51, and the reaction product 300 made of Al—Si, for example, is formed. In addition, for example, N⁺-layer 53 is formed in the semiconductor substrate 10, and the bonding wire 200 is connected to the N⁺-layer 53 similarly. Thus, the semiconductor substrate 10 can be maintained to a reference potential.

According to the pressure sensor as the semiconductor device shown in FIGS. 12A, 12B, the conduction between the connecting portion 200 and the semiconductor substrate 10 can be appropriately secured without providing the electrode pad for the connecting portion in the semiconductor substrate, which is similar to the above-described embodiments.

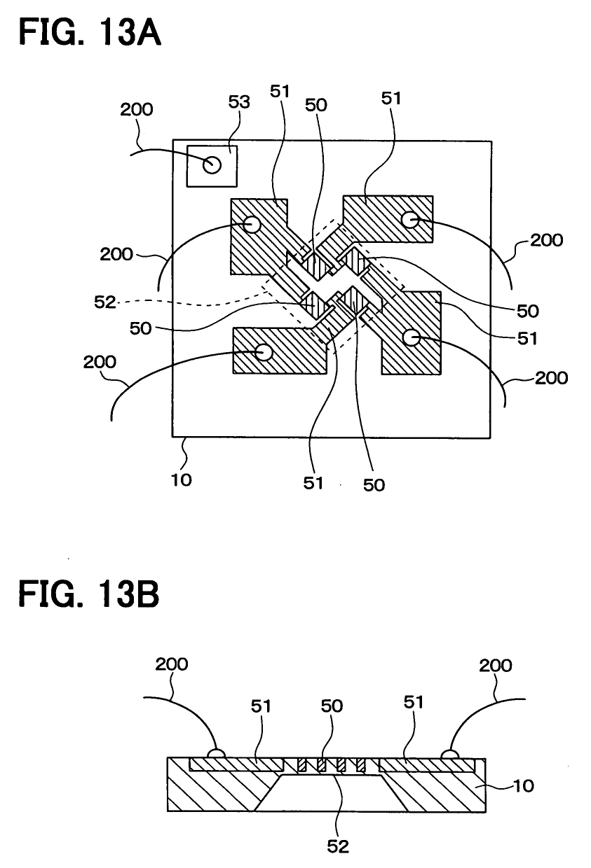

Moreover, as shown in FIGS. 13A, 13B, the reaction product may not exist in the pressure sensor like this. FIGS. 13A, 13B are figures showing a structure of the pressure sensor, in which the reaction product 300 does not exist in the pressure sensor shown in FIGS. 12A, 12B. FIG. 13A is a schematic plan view of the pressure sensor, and FIG. 13B is a schematic cross-sectional view of FIG. 13A.

### Fourth Embodiment

Further, the semiconductor device of the present invention may be a MOS transistor, a BIP (bipolar transistor) or the like, in addition to the above-described semiconductor device. These semiconductor devices have an effect to an analog circuit and a power transistor.

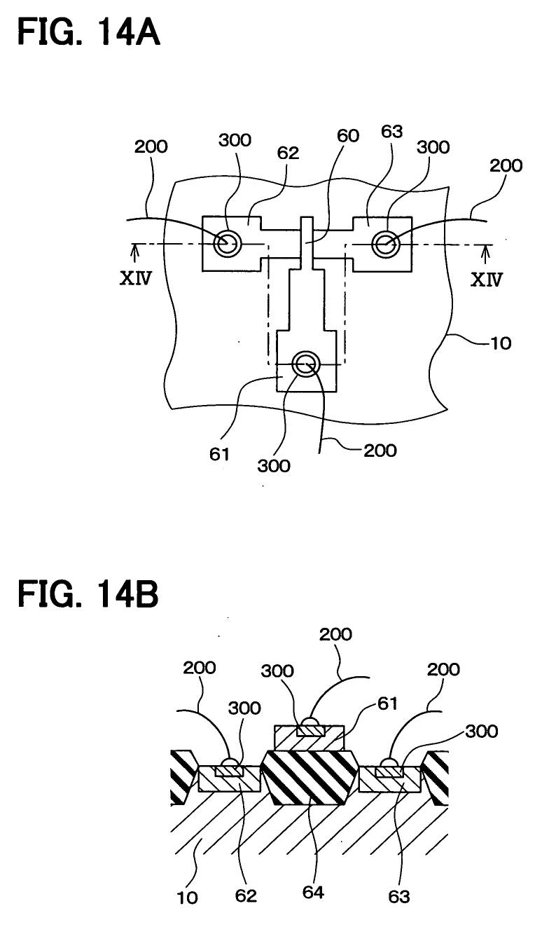

An example is shown in FIGS. 14A, 14B, in which a general MOS transistor is used. FIG. 14A is a schematic plan view of the MOS transistor, and FIG. 14B is a schematic cross-sectional view taken along line XIV-XIV in FIG. 14A. A gate 60, a gate wiring 61, a source 62 and a drain 63 are formed in the semiconductor substrate 10, and each portion 60-63 is constructed as the element portion.

Here, for example, the gate 60 and the gate wiring 61 are formed of polysilicon, and the source 62 and the drain 63 are made of the N⁺ layer. Further, as shown in FIG. 14B, the element portions 60-63 are separated from each other by an insulating film 64, e.g., silicon oxide film.

Then, the bonding wire 200 is electrically connected to the gate wiring 61, the source 62 and the drain 63 so that a reaction product made of Al—Si is formed, for example.

According to the MOS transistor, the conduction between the connecting portion 200 and the semiconductor substrate 10 can be secured appropriately without providing the electrode pad for the connecting portion in the semiconductor substrate, which is similar to the above-described embodiments. Moreover, in this case, the reaction product 300 may not exist.

Thus, a substantial point of the present disclosure is to electrically connect the connecting portion and the semiconductor substrate by making the connecting portion to be directly in contact with the surface of the semiconductor substrate, in the semiconductor device including the semiconductor substrate, the element portion provided in the semiconductor substrate, and the connecting portion, which is electrically connected to the semiconductor substrate and formed of the conductive material in order to perform the electrical connection to the outside.

Further, a second substantial point of the present disclosure is to electrically connect the connecting portion and the semiconductor substrate by forming the reaction product reacted between the conductive material constructing the connecting portion and a semiconductor constructing the semiconductor substrate in the contact portion in the thermal treatment and the like. The design of the other parts can be changed arbitrarily.

The present disclosure includes the following aspects.

According to a first aspect of the present disclosure, a semiconductor device includes a semiconductor substrate, an element portion provided in the semiconductor substrate, and a connecting portion connected to the semiconductor substrate electrically, in which the connecting portion is formed of a conductive material in order to perform an electrical connection to an outside. The connecting portion is directly in contact with a surface of the semiconductor substrate. Thus, the connecting portion and the semiconductor substrate are connected electrically.

According to it, a conduction between the connecting portion and the semiconductor substrate can be appropriately secured without providing an electrode pad for the connecting portion in the semiconductor substrate in a conventional way. This is because the connecting portion and the semiconductor substrate are connected electrically by making the connecting portion to be directly in contact with the surface of the semiconductor substrate.

Therefore, according to the present disclosure, in the semiconductor device including the semiconductor substrate, the element portion provided in the semiconductor substrate, and the connecting portion, which is electrically connected to the semiconductor substrate and formed of the conductive material in order to perform the electrical connection to the outside, inexpensive construction can be realized, in which the electrode pad for the connecting portion is not required.

Alternatively, the semiconductor device may further include a reaction product portion. The reaction product portion is disposed in a contact portion of the semiconductor substrate and the connecting portion. The reaction product portion is formed by a material reacted between a conductive material constructing the connecting portion and a semiconductor constructing the semiconductor substrate.

Alternatively, the connecting portion may be a bonding wire.

Alternatively, the conductive material constructing the connecting portion may be Al, the semiconductor constructing the semiconductor substrate may be Si, and the material constructing the reaction product portion may be Al—Si.

Alternatively, the element portion may include a movable member displaceable to the semiconductor substrate in accordance with an applied physical quantity. In this case, the element portion can be a movable member displaceable to the semiconductor substrate in accordance with an applied physical quantity. Therefore, a favorable aspect for a physical quantity sensor such as an acceleration sensor and an angular speed sensor can be realized.

According to a second aspect of the present disclosure, a method of producing a semiconductor device includes a step of preparing a semiconductor substrate, a step of providing an element portion in the semiconductor substrate, and a step of connecting a connecting portion to the semiconductor substrate electrically, in which the connecting portion is formed of a conductive material in order to perform the electrical connection to an outside. The step of connecting includes a contacting step, in which the connecting portion is made to be directly in contact with a surface of the semiconductor substrate, and a forming step, in which a thermal treatment is performed at the contact portion such that a reaction product portion is formed by reacting the conductive material providing the connecting portion and a semiconductor providing the semiconductor substrate in the contact portion.

According to it, the method of producing the semiconductor device can be provided, in which the semiconductor device having the reaction product portion can be appropriately produced.

Alternatively, the thermal treatment may be performed by irradiating a laser locally to the contact portion.

Alternatively, the connecting portion may be a bonding wire, and the thermal treatment may be performed at the same time as a wire bonding is performed on a surface of the semiconductor substrate.

Alternatively, the connecting portion may be a bonding wire, and the thermal treatment may be performed after a wire bonding is performed on a surface of the semiconductor substrate.

Alternatively, the conductive material providing the connecting portion may be Al, the semiconductor providing the semiconductor substrate may be Si, and the material providing the reaction product portion may be Al—Si.

While the present invention is disclosed with reference to preferred embodiments thereof, it is to be understood that the present invention is not limited to the preferred embodiments and constructions. The invention is intended to cover various modification and equivalent arrangements. The invention is intended to cover various combinations and configurations, which are preferred, other combinations and configurations, including more, less or only a single element, are also within the spirit and scope of the present invention.

1. A semiconductor device comprising:
a semiconductor substrate;
an element portion disposed on the semiconductor substrate;
a connecting portion connected to the semiconductor substrate electrically and made of a conductive material in order to perform an electrical connection to an external circuit; and
a reaction product portion, wherein
the connecting portion is directly in contact with a surface of the semiconductor substrate,
the connecting portion and the semiconductor substrate are connected electrically,
the reaction product portion is disposed in a contact portion of the semiconductor substrate and the connecting portion, and
the reaction product portion is made of a material reacted between a conductive material constructing the connecting portion and a semiconductor constructing the semiconductor substrate.

2. (canceled)

3. The semiconductor device according to claim 1, wherein
the connecting portion is a bonding wire.

4. The semiconductor device according to claim 1, wherein
the conductive material constructing the connecting portion is Al,
the semiconductor constructing the semiconductor substrate is Si, and
the material constructing the reaction product portion is Al—Si.

5. The semiconductor device according to claim 1, wherein
the element portion includes a movable member displaceable to the semiconductor substrate in accordance with an applied physical quantity.

6. A method of producing a semiconductor device comprising steps of:
preparing a semiconductor substrate;
forming an element portion on the semiconductor substrate; and
connecting a connecting portion to the semiconductor substrate electrically, wherein
the connecting portion is formed of a conductive material in order to perform an electrical connection to an external circuit, and
the step of connecting includes step of:
contacting the connecting portion directly to a surface of the semiconductor substrate; and
forming a reaction product portion in the contact portion by reacting the conductive material providing the connecting portion and a semiconductor providing the semiconductor substrate in a thermal treatment.

7. The method of producing the semiconductor device according to claim 6, wherein
the thermal treatment is performed by irradiating a laser locally to the contact portion.

8. The method of producing the semiconductor device according to claim 6, wherein
the connecting portion is a bonding wire, and
the thermal treatment is performed at the same time as a wire bonding of the bonding wire is performed on a surface of the semiconductor substrate.

9. The method of producing the semiconductor device according to claim 6, wherein
the connecting portion is a bonding wire, and
the thermal treatment is performed after a wire bonding of the bonding wire is performed on a surface of the semiconductor substrate.

10. The method of producing the semiconductor device according to claim 6, wherein
the conductive material providing the connecting portion is Al,
the semiconductor providing the semiconductor substrate is Si, and
the material providing the reaction product portion is Al—Si.
